(19) United States
(12) Patent Application Publication
(10) Pub. No.: US 2025/0393152 A1
(43) Pub. Date: Dec. 25, 2025

(54) Server Information Handling System Peripheral Riser Module System

(71) Applicant: Dell Products L.P., Round Rock, TX (US)

(72) Inventors: Pei-Chuan Hsieh, Xizhi Dist. (TW); Kuang-Hsi Lin, Bade Dist. (TW); Po Li Hsieh, Taoyuan (TW)

(21) Appl. No.: 18/748,660

(22) Filed: Jun. 20, 2024

(51) Int. Cl. H05K 7/14; G06F 1/18

(52) U.S. Cl. CPC H05K 7/1489; G06F 1/185; H05K 7/1492

(57) ABSTRACT

A peripheral mounting system. The peripheral mounting system includes a first slot, the first slot being configured to mount a first peripheral component and a first peripheral connector component, the first peripheral component and the first peripheral connector component corresponding a first component standard and, a second slot, the second slot being configured to mount a second peripheral component and a second peripheral connector component, the second peripheral component and the second peripheral connector component corresponding to a second component standard, the first component standard and the second component standard being different component specifications.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with a peripheral mounting system which includes slots for devices which conform to different bus standards.

In one embodiment, the invention relates to a peripheral mounting system for use with an information handling system, comprising: a first slot, the first slot being configured to mount a first peripheral component and a first peripheral connector component, the first peripheral component and the first peripheral connector component corresponding a first component standard; and, a second slot, the second slot being configured to mount a second peripheral component and a second peripheral connector component, the second peripheral component and the second peripheral connector component corresponding to a second component standard, the first component standard and the second component standard being different component specifications.

In another embodiment, the invention relates to peripheral tray system comprising: a chassis; and, a peripheral mounting system mounted to the chassis, the peripheral mounting system comprising a first slot, the first slot being configured to mount a first peripheral component and a first peripheral connector component, the first peripheral component and the first peripheral connector component corresponding a first component standard; and, a second slot, the second slot being configured to mount a second peripheral component and a second peripheral connector component, the second peripheral component and the second peripheral connector component corresponding to a second component standard, the first component standard and the second component standard being different component specifications.

In another embodiment, the invention relates to a system comprising: a chassis; a processor contained within the chassis; a data bus coupled to the processor; and, a peripheral mounting system comprising a first slot, the first slot being configured to mount a first peripheral component and a first peripheral connector component, the first peripheral component and the first peripheral connector component corresponding a first component standard; and, a second slot, the second slot being configured to mount a second peripheral component and a second peripheral connector component, the second peripheral component and the second peripheral connector component corresponding to a second component standard, the first component standard and the second component standard being different component specifications.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A, 4B and 4C, generally referred to as FIG. 4, respectively, show a top perspective view, a cut away top perspective view and a bottom perspective view of a peripheral mounting system.

FIG. 5 shows an exploded perspective view of a peripheral mounting system.

FIGS. 6A and 6B, generally referred to as FIG. 6, show top views of an OCP peripheral component and a floating OCP component receiving assembly.

FIGS. 7A and 7B, generally referred to as FIG. 7, show a cut away perspective view of a portion of a peripheral mounting system which includes a latching component in an unlocked orientation and a locked orientation, respectively.

FIGS. 8A and 8B, generally referred to as FIG. 8, show a cut away side view of portion of a peripheral mounting system which includes a latching component in an unlocked orientation and a locked orientation, respectively.

FIGS. 9A and 9B, generally referred to as FIG. 9, show top views of a PCIe peripheral component and a PCIe component receiving assembly.

FIGS. 10A, 10B and 10C, generally referred to as FIG. 10, respectively show an exploded top view of a peripheral mounting system, a perspective top view of a peripheral mounting system and a perspective bottom view of a peripheral mounting system.

### DETAILED DESCRIPTION

Various aspects of the disclosure include an appreciation that it is known to provide information handling systems with devices which conform to various standard specifications. Various aspects of the disclosure include an appreciation that these standard specifications include an open compute project (OCP) foundation specification and a Peripheral Component Interconnect express (PCIe) specification.

Various aspects of the disclosure include an appreciation that an example of devices which conform to the OCP standard specification include OCP type network devices. Various aspects of the disclosure include an appreciation that an OCP type network device may be instantiated as an OCP network card. Various aspects of the present disclosure include an appreciation that an OCP network card is a standard form factor card that is commonly supported in servers. Various aspects of the present disclosure include an appreciation that known OCP card network cards mate with an OCP card receiving component circuit board via a straddle connector that resides on a receiving board of the OCP card receiving component. Various aspects of the present disclosure include an appreciation that the OCP card receiving component may be configured within a motherboard of an information handling system or may be a stand-alone component. When the OCP card receiving component is configured as a stand-alone component, the OCP card receiving component is referred to as a floating OCP component (i.e., FLOP component) or floating OCP receiving assembly (i.e., FLOP receiving assembly).

Various aspects of the disclosure include an appreciation that an example of devices which conform to the PCIe standard specification include PCIe type network devices. Various aspects of the disclosure include an appreciation that a PCIe type network device may be instantiated as a PCIe network card. Various aspects of the present disclosure include an appreciation that a PCIe network card is a standard form factor card that is commonly supported in servers. Various aspects of the present disclosure include an appreciation that known PCIe network cards mate with PCIe card receiving component circuit board via a PCIe connector that resides on a receiving board of the PCIe card receiving component. Various aspects of the present disclosure include an appreciation that many known PCIe network cards include connectors positioned along a side edge of the PCIe network card. Various aspects of the present disclosure include an appreciation that many known PCIe connectors are located along a side of a PCIe riser cage.

Various aspects of the present disclosure include an appreciation that it would be desirable to provide a single riser cage that includes an OCP type slot and a PCIe slot within the same riser cage. Various aspects of the present disclosure include an appreciation that it would be desirable to provide a single riser cage which conforms to a 1U rack unit form factor that includes an OCP type slot and a PCIe slot within the same riser cage. Various aspects of the disclosure include an appreciation that it would be desirable to provide an information handling system chassis which includes a riser cage that includes an OCP type slot and a PCIe slot within the same riser cage. Various aspects of the present disclosure include an appreciation that it would be desirable to provide a 1U rack unit form factor information handling system which includes a riser cage that includes an OCP type slot and a PCIe slot within the same riser cage.

A system and method are disclosed for providing a server type information handling system with a peripheral mounting system. In certain embodiments, the server information handling system includes an information handling system chassis which includes a peripheral mounting system that includes an OCP type slot and a PCIe slot within the same riser cage (also referred to as a device bay). In certain embodiments, the information handling system chassis comprises a 1U rack unit form factor information handling system chassis which includes a riser cage that includes an OCP type slot and a PCIe slot within the same riser cage.

In certain embodiments, the riser cage includes an OCP slot which includes a latch mechanism that locks an OCP board notch. In certain embodiments, the riser cage is configured so that the OCP card can be serviced directly without having to remove the riser from the chassis. In certain embodiments, a Floating OCP Peripheral (a FLOP) Board can be used with the riser cage.

In certain embodiments, the riser cage includes a PCIe slot which includes a cable riser feature. In certain embodiments, the riser cage includes a PCIe slot which includes one or more PCIe card retention features. In certain embodiments, the PCIe slot can be configured to receive a PCIe card according to particular system configuration requirements.

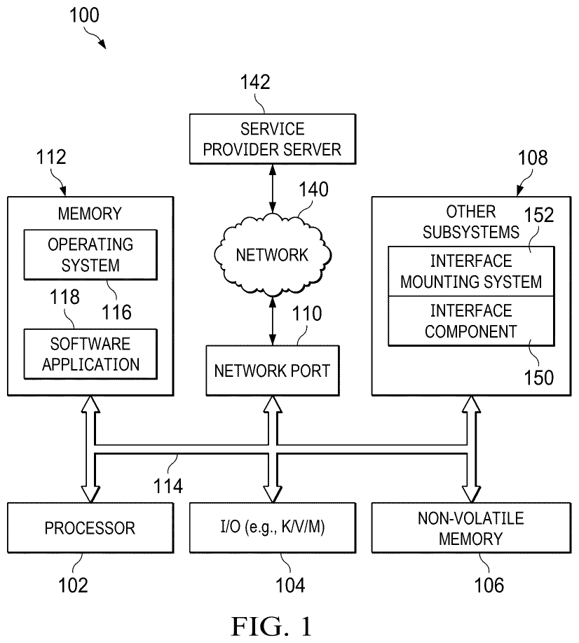

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a peripheral component 150, a peripheral component mounting system 152, or a combination thereof. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the peripheral mounting system 152 includes a plurality of card component slots. In certain embodiments, the peripheral mounting system 152 is configured a riser cage (also referred to as a device bay) that can accommodate a plurality of card components. In certain embodiments, the peripheral mounting system 152 includes a plurality of peripheral component slots. In certain embodiments, the riser cage includes an OCP type slot, a PCIe slot, or a combination thereof, within the same riser cage. In certain embodiments, the information handling system chassis comprises a 1U rack unit form factor information handling system chassis which includes a riser cage that includes an OCP type slot and a PCIe slot within the same riser cage.

In certain embodiments, the riser cage includes an OCP slot which includes a latch mechanism that locks an OCP board notch. In certain embodiments, the riser cage is configured so that the OCP card can be serviced directly without having to remove the riser from the chassis. In certain embodiments, a Floating OCP Peripheral (a FLOP) Board can be used with the riser cage.

In certain embodiments, the riser cage includes a PCIe slot which includes a cable riser feature. In certain embodiments, the riser cage includes a PCIe slot which includes one or more PCIe card retention features. In certain embodiments, the PCIe slot can be configured to receive a PCIe card according to particular system configuration requirements.

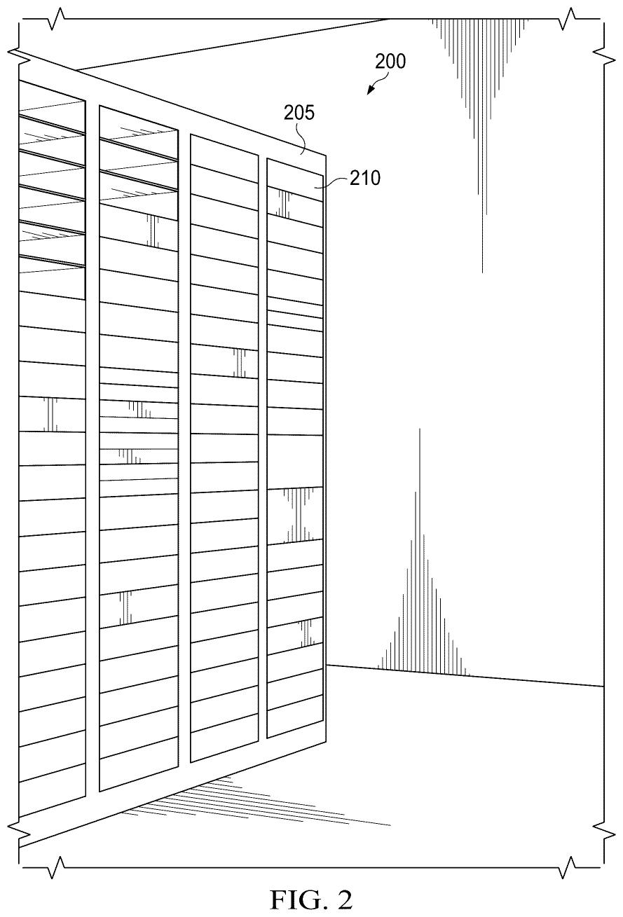

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuously with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high and a 4U rack height is substantially (i.e., +/−20%) 7.0″ high.

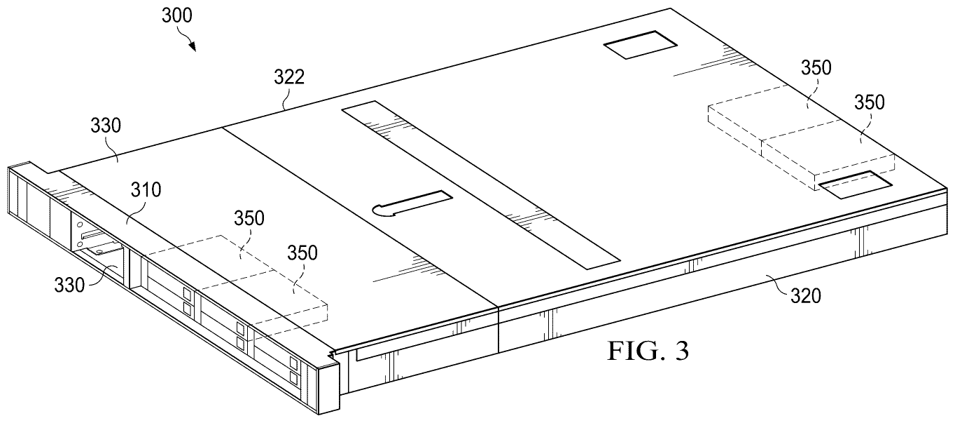

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes one or more bays 350 via which components may be mounted to the blade type information handling system. In certain embodiments, a peripheral system such as a multi-slot peripheral mounting system may be mounted within each bay 350.

In certain embodiments, the card component mounting system 152 can accommodate a plurality of card component slots. In certain embodiments, the card component mounting system 152 includes a riser cage that can accommodate a plurality of card components. In certain embodiments, the riser cage includes an OCP type slot, a PCIe slot, or a combination thereof, within the same riser cage. In certain embodiments, the information handling system chassis comprises a 1U rack unit form factor information handling system chassis which includes a riser cage that includes an OCP type slot and a PCIe slot within the same riser cage.

In certain embodiments, the riser cage includes an OCP slot which includes a latch mechanism that locks an OCP board notch. In certain embodiments, the riser cage is configured so that the OCP card can be serviced directly without having to remove the riser from the chassis. In certain embodiments, a Floating OCP Peripheral (a FLOP) Board can be used with the riser cage.

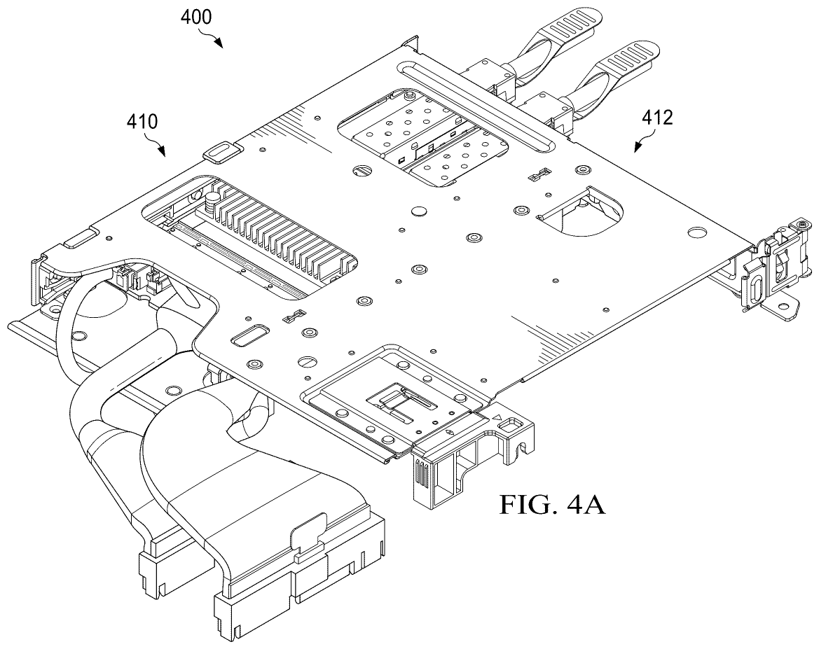

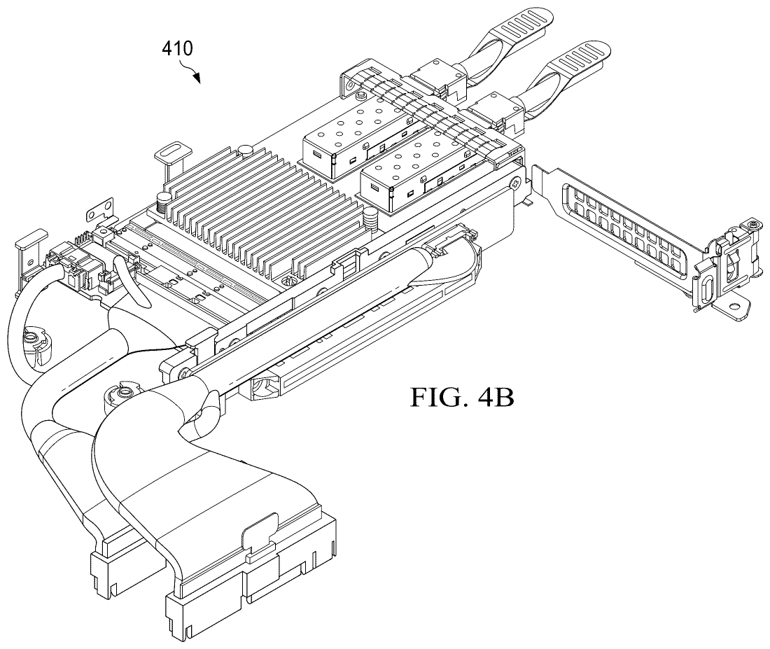

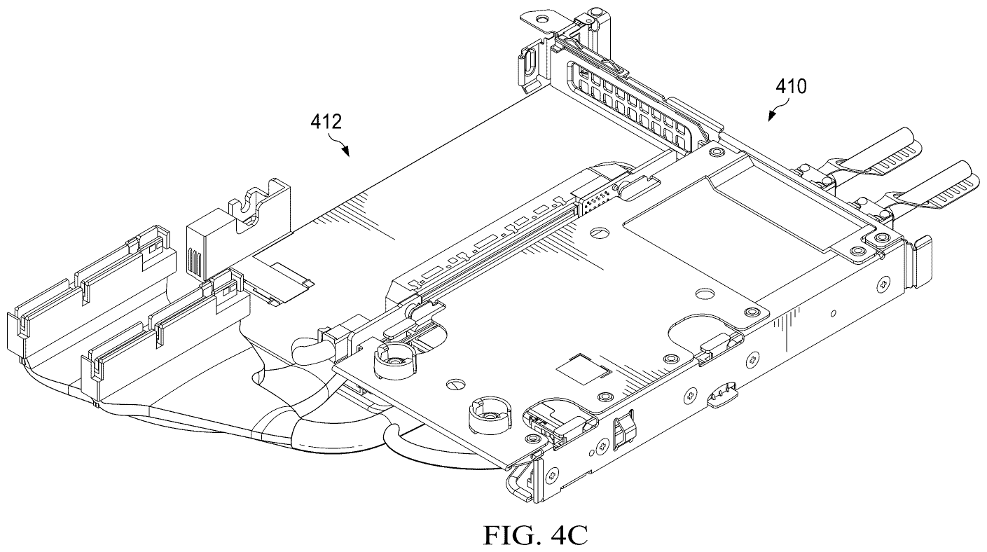

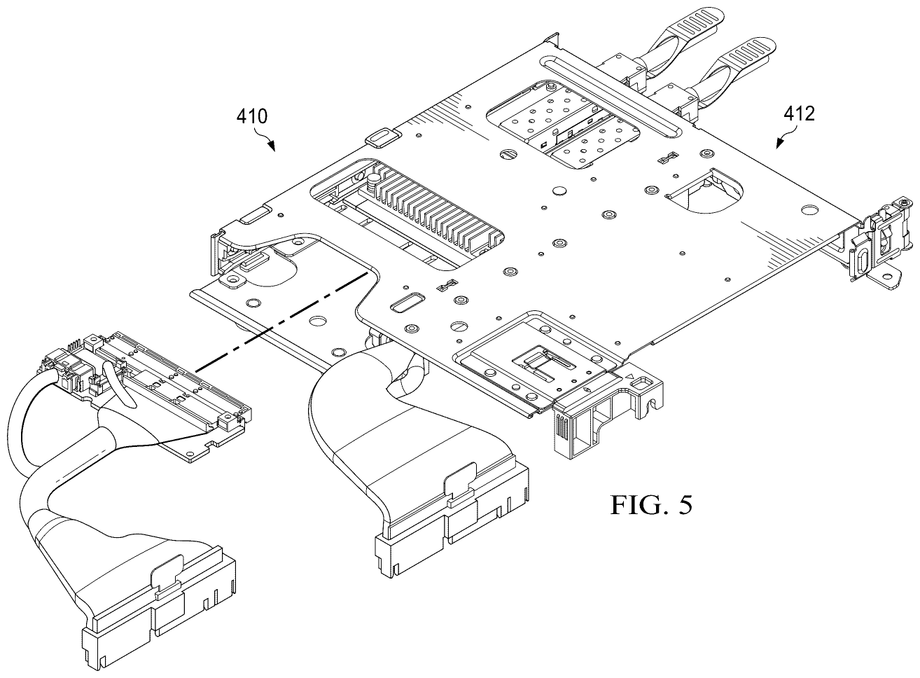

FIGS. 4A, 4B and 4C, generally referred to as FIG. 4, show a plurality of views of a multi-slot peripheral mounting system 400. FIG. 5 shows an exploded perspective view of a peripheral mounting system. More specifically, FIG. 4A shows a top perspective view of a multi-slot peripheral mounting system 400. FIG. 4B shows a cut-away top perspective view of a multi-slot peripheral mounting system 400. FIG. 4C shows a bottom perspective view of a multi-slot peripheral mounting system 400. In certain embodiments, the multi-slot peripheral mounting system 400 corresponds to peripheral mounting system 152.

In certain embodiments, the peripheral mounting system 400 includes a plurality of card component slots. In certain embodiments, the peripheral mounting system 400 is configured as a riser cage (also referred to as a device bay) that can accommodate a plurality of card components. In certain embodiments, the peripheral mounting system 400 includes a plurality of peripheral component slots within a single peripheral mounting system 400. In certain embodiments, the peripheral mounting system 400 includes a first slot 410 and a second slot 412. In certain embodiments, the first slot 410 is configured to mount a first peripheral component. In certain embodiments, the second slot 412 is configured to mount a second component. In certain embodiments, the first component and the second component correspond to a different standard specification. In certain embodiments, the first slot 410 is configured to mount a first peripheral connector component. In certain embodiments, the second slot 412 is configured to mount a second connector component. In certain embodiments, the first connector component and the second connector component correspond to a different standard specification. As used herein, a slot broadly refers to a portion of a peripheral mounting system in which a peripheral component may be mounted. In certain embodiments, the slot includes mechanical guides for fitting the peripheral component in a predetermined position within the peripheral mounting system.

In certain embodiments, the first slot 410 includes an OCP type slot. In certain embodiments, the second slot includes a PCIe slot. In certain embodiments, the first peripheral component includes an OCP type component. In certain embodiments, the second component includes a PCIe type component. In certain embodiments, the first peripheral connector component includes an OCP type connector component. In certain embodiments, the OCP type connector component includes a floating OCP type connector component. In certain embodiments, the second connector component includes a PCIe type connector component.

In certain embodiments, the OCP connector component includes an OCP type connector. In certain embodiments, the PCIe connector component includes a PCIe type connector. In certain embodiments, when the OCP type connector and the PCIe type connector are installed on the mounting system, the OCP type connector and the PCIe type connection are substantially perpendicular to each other.

In certain embodiments, the OCP component includes a plurality of connection contacts extending along a back edge of the OCP component. In certain embodiments, the connector of the OCP connector component is positioned to physically and electrically couple with the plurality of contacts extending along the back edge of the OCP component. In certain embodiments, the OCP connector includes an edge board connector which electrically and physically mates with the plurality of connector leads of the OCP component.

In certain embodiments, the PCIe component includes a plurality of connection contacts extending along a side edge of the OCP component. In certain embodiments, the connector of the PCIe connector component is positioned to physically and electrically couple with the plurality of contacts extending along the side edge of the OCP component. In certain embodiments, the PCIe connector includes an edge board connector which electrically and physically mates with the plurality of connector leads of the PCIe component.

In certain embodiments, the peripheral mounting system 400 is configured correspond to a 1U rack unit form factor. In certain embodiments, the peripheral mounting system 400 is configured to be mounted within a 1U rack unit form factor information handling system chassis. within a 1U rack unit form factor information handling system chassis. In certain embodiments, the peripheral mounting system 400 is configured with the first slot 410 and the second slot 412 are substantially side by side relative to each other to provide a peripheral mounting system 400 with a height which can be mounted within a 1U rack unit form factor information handling system chassis. In certain embodiments, the peripheral mounting system 400 is configured with the first slot 410 and the second slot 412 are mounted to a single mounting component 420 of the peripheral mounting system 400.

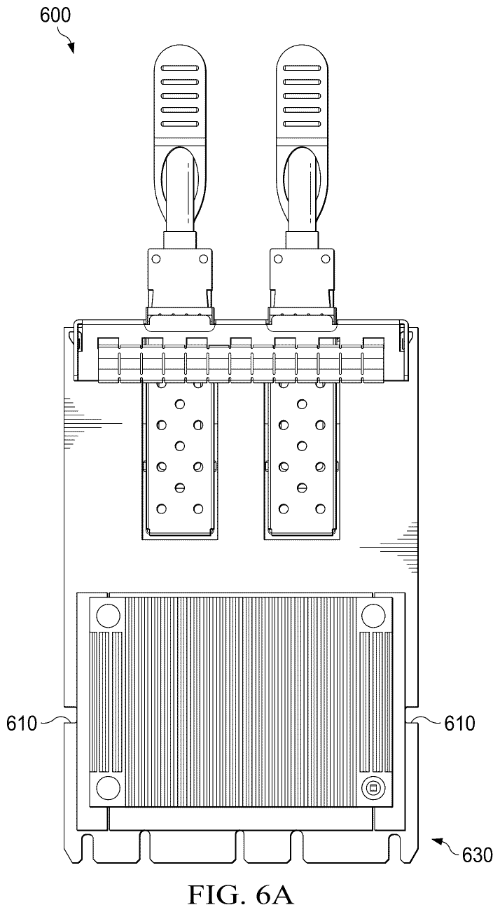

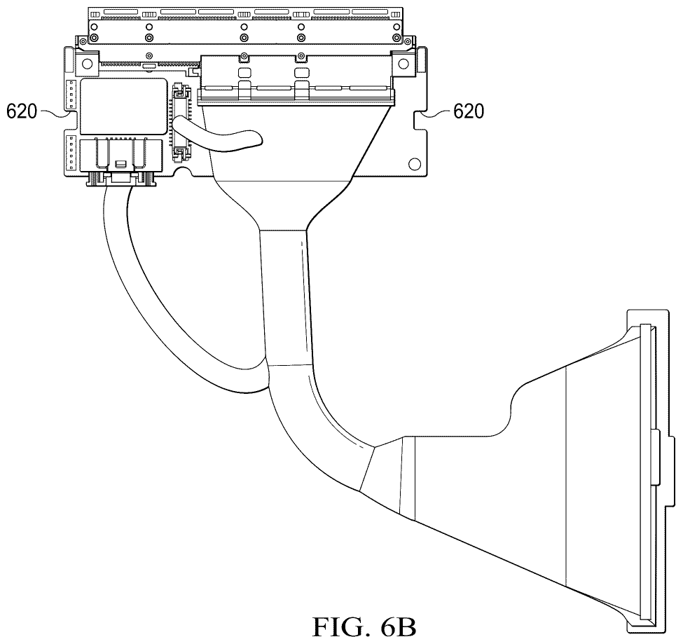

FIGS. 6A and 6B, generally referred to as FIG. 6, show top views of an OCP peripheral component 600 and a floating OCP component receiving assembly 605. In certain embodiments, the OCP peripheral component 600 and the floating OCP component receiving assembly 605 correspond to an OCP standard specification.

In certain embodiments, the OCP peripheral component 600 defines one or more mounting notches 610. Various aspects of the present disclosure include an appreciation that often the one or more mounting notches 610 are configured to receive a projection of a rotating connection device. Various aspects of the present disclosure include an appreciation that often the rotating connection device rotates from a vertical orientation to a horizontal orientation. Various aspects of the present disclosure include an appreciation that the vertical orientation corresponds to an unlatched configuration and the horizontal orientation corresponds to a latched configuration. Various aspects of the present disclosure include an appreciation that when the rotating connection device is in the latched configuration, a projection of the rotating connection device interacts with at least one mounting notch of the OCP peripheral component.

In certain embodiments, the OCP component receiving assembly 605 defines one or more mounting notches 620. Various aspects of the present disclosure include an appreciation that often the one or more mounting notches 620 are configured to interact with a receiving assembly mounting device. Various aspects of the present disclosure include an appreciation that the mounting device often includes a fastener via which the OCP component receiving assembly 605 is affixed to a printed circuit board of an OCP device bay.

In certain embodiments, the OCP component 600 includes a plurality of connection contacts extending along a back edge 630 of the OCP component. In certain embodiments, the connector of the OCP component receiving assembly 605 is positioned to physically and electrically couple with the plurality of contacts extending along the back edge 630 of the OCP component. In certain embodiments, the OCP connector includes an edge board connector which electrically and physically mates with the plurality of connector leads of the OCP component.

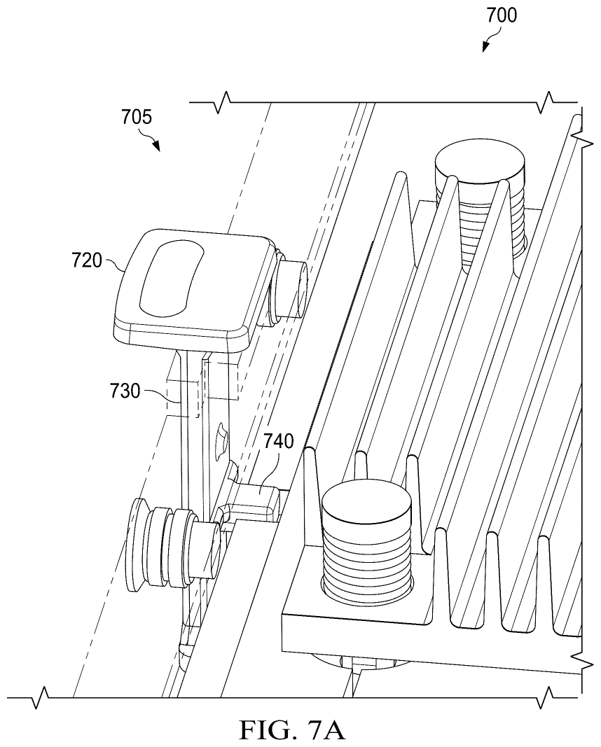

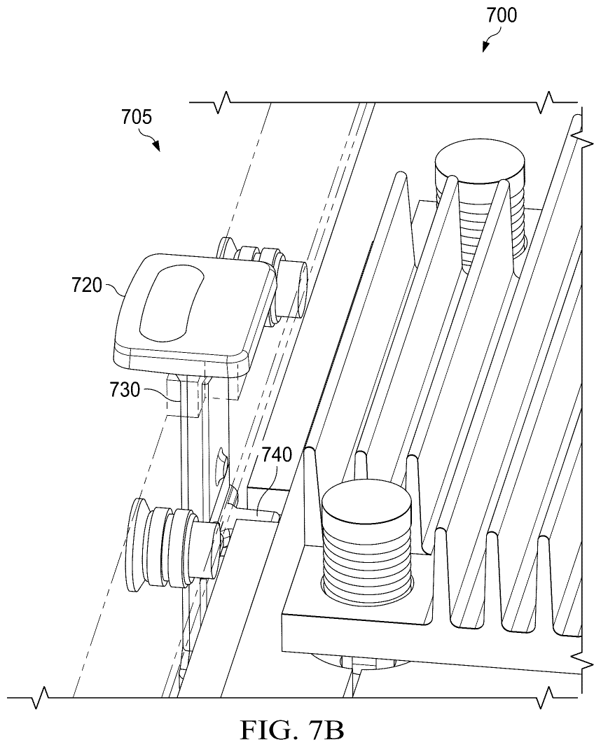

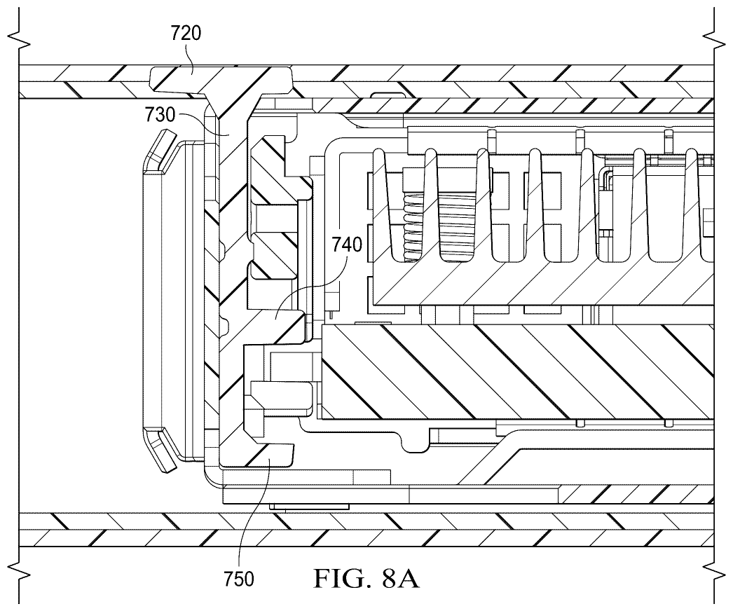

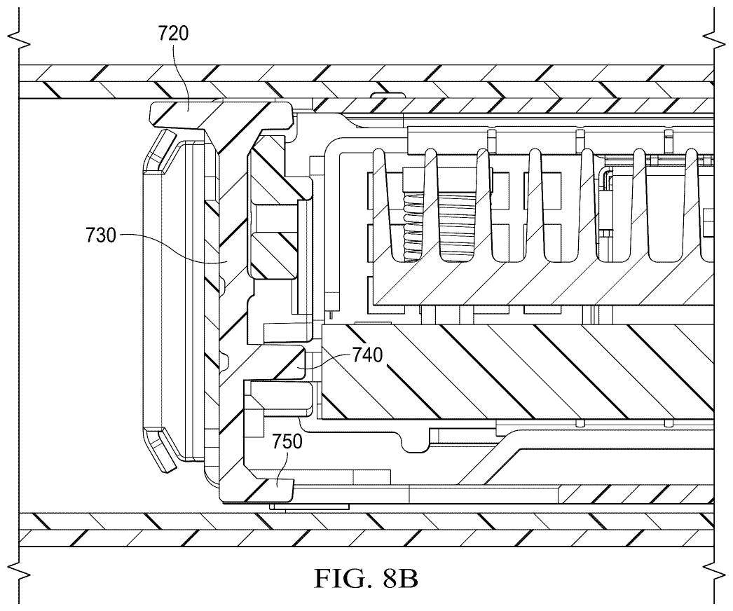

FIGS. 7A and 7B, generally referred to as FIG. 7, show views of a portion of a peripheral mounting system 700 which includes a latching mechanism 705. More specifically, FIG. 7A shows a cut away perspective view of portion of a peripheral mounting system 700 which includes a latching mechanism 705 in an unlocked orientation. FIG. 7B shows a cut away perspective view of portion of a peripheral mounting system 700 which includes a latching mechanism 705 in a locked orientation. FIGS. 8A and 8B, generally referred to as FIG. 8, show views of a portion of the peripheral mounting system 700. More specifically, FIG. 8A shows a cut away perspective view of portion of a peripheral mounting system 700 which includes a latching mechanism 705 in an unlocked orientation. FIG. 8B shows a cut away perspective view of a portion of a peripheral mounting system 700 which includes a latching mechanism 705 in a locked orientation.

In certain embodiments, the latching mechanism 705 is configured to interface with an OCP component notch. In certain embodiments, the peripheral mounting system is configured so that the OCP component can be serviced directly without having to remove the peripheral mounting system from the information handling system chassis. In certain embodiments, a Floating OCP Peripheral (a FLOP) Board can be used with the peripheral mounting system.

In certain embodiments, the latching mechanism includes a top portion 720, a post 730, a latching projection 740, a travel restriction projection 750, or a combination thereof. In certain embodiments, the top portion includes a substantially flat wall. In certain embodiments, the top portion 720 is substantially horizontal. In certain embodiments, the top portion 720 is configured to interact with a top wall of a chassis when the latching mechanism 705 is in an open configuration. In certain embodiments, the top portion 720 is configured to interact with the top wall of the chassis when the top wall of the chassis is closed to cause the latching mechanism 705 to move from an open configuration to a closed configuration.

In certain embodiments, the post 730 extends substantially downwardly from the top portion 720. In certain embodiments, the post extends substantially perpendicularly from the top portion 720. In certain embodiments, the latching projection 740 extends substantially outwardly from the post 730. In certain embodiments, the latching portion 740 is configured to interact with a notch of an OCP component, an OCP component mounting component, or a combination thereof, the latching mechanism 705 is in a closed configuration. In certain embodiments, the latching projection 740 extends substantially perpendicularly from the post 730. In certain embodiments, the travel restriction projection 750 is configured to interact with a bottom wall of a chassis when the latching mechanism 705 is in a closed configuration.

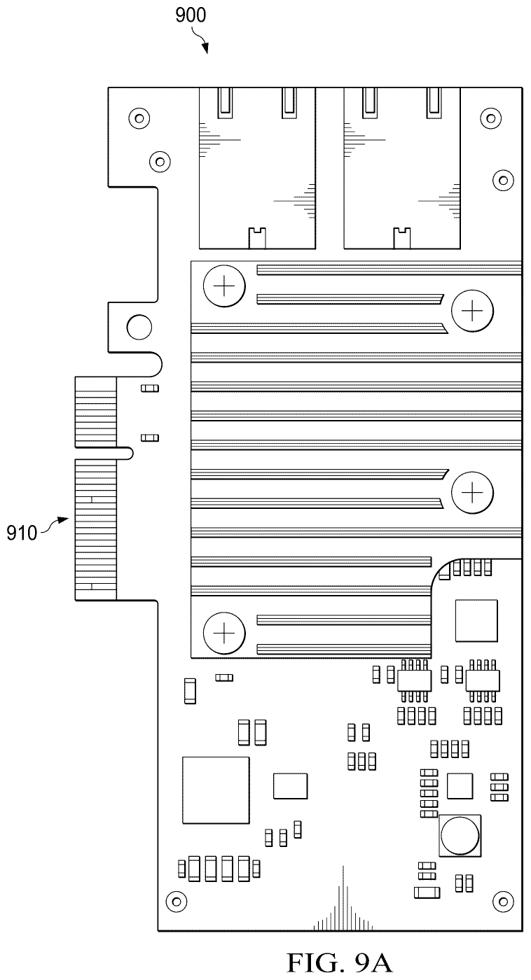

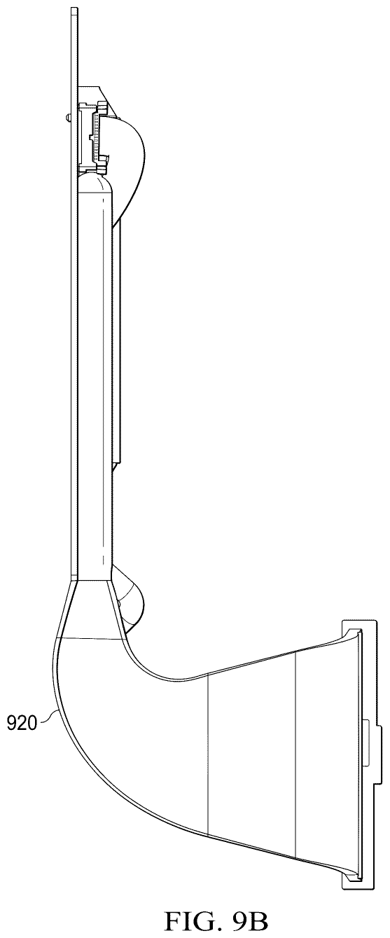

FIGS. 9A and 9B, generally referred to as FIG. 9, show top views of a PCIe peripheral component 900 and a PCIe component receiving assembly 905. More specifically, the PCIe peripheral component 900 and the PCIe component receiving assembly 905 correspond to PCIe standard specification.

In certain embodiments, the PCIe component includes a plurality of connection contacts extending along a side edge 910 of the OCP component. In certain embodiments, a connector 920 of the PCIe connector component is positioned to physically and electrically couple with the plurality of contacts extending along the side edge of the OCP component. In certain embodiments, the PCIe connector 920 includes an edge board connector which electrically and physically mates with the plurality of connector leads of the PCIe component

In certain embodiments, the PCIe component includes a PCIe component board 930. In certain embodiments, the PCIe component board 930 a width of the component board may vary based upon a type of PCIe system configuration.

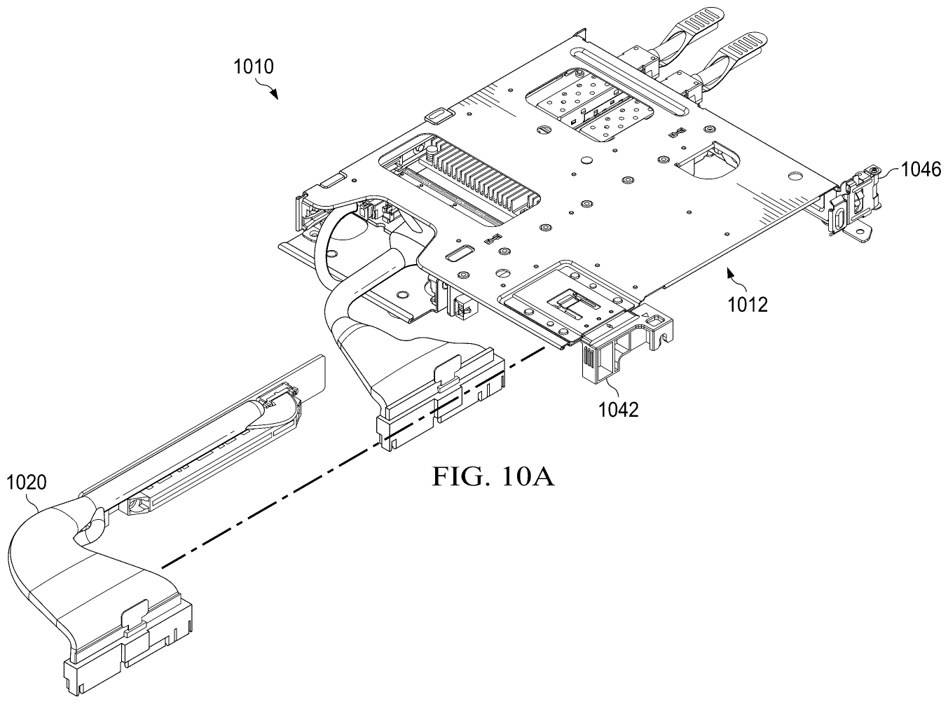

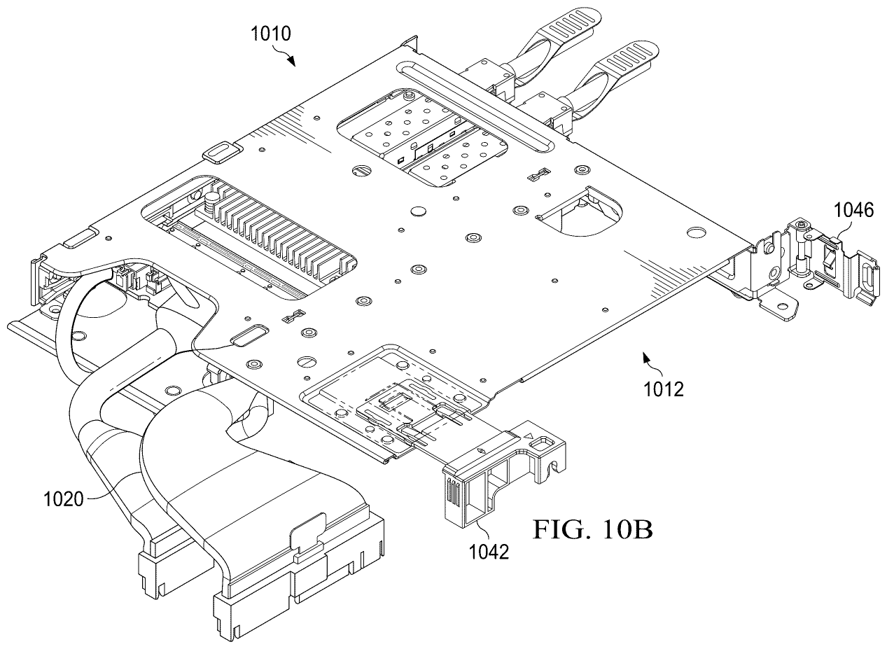

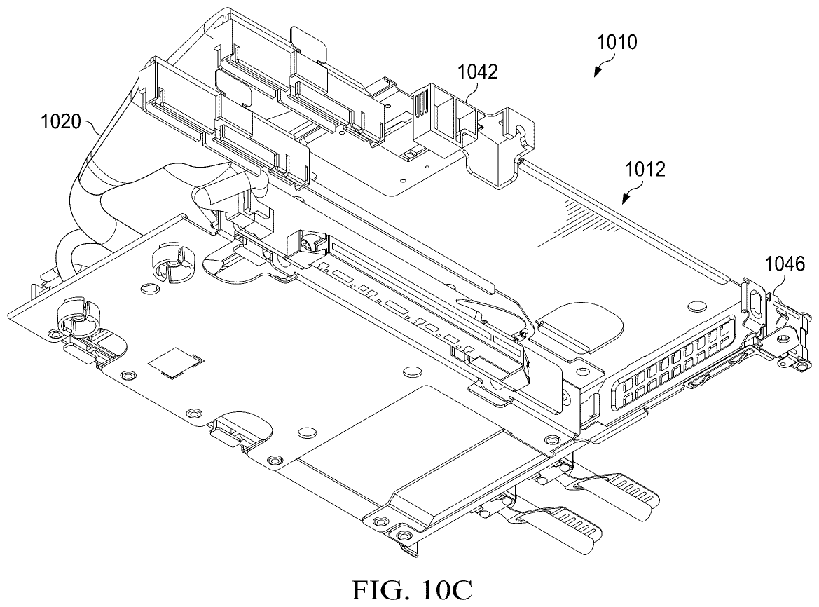

FIGS. 10A, 10B and 10C, generally referred to as FIG. 10, show perspective views of a peripheral mounting system 1000. More specifically, FIG. 10A shows an exploded top view of a peripheral mounting system. FIG. 10B shows a perspective top view of a peripheral mounting system. FIG. 10C shows a perspective bottom view of a peripheral mounting system.

In certain embodiments, the peripheral mounting system 1000 includes a PCIe mounting component portion 1010. In certain embodiments, the PCIe mounting component portion 1010 includes a PCIe mounting slot 1012. In certain embodiments, the component mounting system 1010 includes a cable riser feature 1020. In certain embodiments, the cable riser feature 1020 physically couples a PCIe connection component 1030 to the component mounting system 1010. In certain embodiments, the PCIe connection component 1030 is physically coupled with the component mounting system 1010 such that a connector of the PCIe connection component 1030 is mounted along a side of the PCIe mounting slot.

In certain embodiments, the component mounting system 1010 includes a first component retention feature 1040, a second component retention feature 1042, or a combination thereof. In certain embodiments, the PCIe slot can be configured to receive a PCIe card according to particular system configuration requirements. In certain embodiments, the first component retention feature 1040, the second component retention feature 1042, or a combination thereof may be configured to receive a PCIe component having a particular system configuration. In certain embodiments, the particular system configuration can have a width of PCIe card defined by the particular system configuration.

In certain embodiments, the first retention feature 1040 is configured to pivot between an open configuration and a closed configuration. In certain embodiments, the closed configuration of the first retention feature 1040 physically mounts a PCIe component within a PCIe slot. In certain embodiments, the second retention feature 1042 is configured to slide between an open configuration and a closed configuration. In certain embodiments, the closed configuration of the second retention feature 1042 physically mounts a PCIe component within a PCIe slot. In certain embodiments, a depth of the second retention feature 1042 when in the closed configuration can vary based upon a particular system configuration of the PCIe component.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A peripheral mounting system for use with an information handling system, comprising:
a first slot, the first slot being configured to mount a first peripheral component and a first peripheral connector component, the first peripheral component and the first peripheral connector component corresponding a first component standard; and,
a second slot, the second slot being configured to mount a second peripheral component and a second peripheral connector component, the second peripheral component and the second peripheral connector component corresponding to a second component standard, the first component standard and the second component standard being different component specifications.

2. The peripheral mounting system of claim 1, wherein:
the peripheral mounting system is configured to be mounted within an information handling system chassis conforming to a 1U information handling system form factor.

3. The peripheral mounting system of claim 1, wherein:
the first peripheral connector component includes a first peripheral component connector;
the second peripheral connector component includes a second peripheral component connector; and,
the first peripheral component connector and the second peripheral component connector are mounted in the peripheral mounting system substantially perpendicularly to each other.

4. The peripheral mounting system of claim 1, wherein:
the first slot includes a latching mechanism, the latching mechanism being configured to mount at least one of the first peripheral component and the first peripheral connector component to the peripheral mounting system.

5. The peripheral mounting system of claim 1, wherein:
the first component standard comprises an open compute project (OCP) component standard; and,
the second component standard comprises a Peripheral Component Interconnect express (PCIe) component standard.

6. The peripheral mounting system of claim 5, wherein:
the first connector component comprises a floating OCP (FLOP) connector component.

7. A peripheral tray system comprising:
a chassis; and,
a peripheral mounting system mounted to the chassis, the peripheral mounting system comprising
a first slot, the first slot being configured to mount a first peripheral component and a first peripheral connector component, the first peripheral component and the first peripheral connector component corresponding a first component standard; and,
a second slot, the second slot being configured to mount a second peripheral component and a second peripheral connector component, the second peripheral component and the second peripheral connector component corresponding to a second component standard, the first component standard and the second component standard being different component specifications.

8. The peripheral tray system of claim 7, wherein:
the peripheral mounting system is configured to be mounted within an information handling system chassis conforming to a 1U information handling system form factor.

9. The peripheral tray system of claim 7, wherein:
the first peripheral connector component includes a first peripheral component connector;
the second peripheral connector component includes a second peripheral component connector; and,
the first peripheral component connector and the second peripheral component connector are mounted in the peripheral mounting system substantially perpendicularly to each other.

10. The peripheral tray system of claim 7, wherein:
the first slot includes a latching mechanism, the latching mechanism being configured to mount at least one of the first peripheral component and the first peripheral connector component to the peripheral mounting system.

11. The peripheral tray system of claim 7, wherein:
the first component standard comprises an open compute project (OCP) component standard; and,
the second component standard comprises a Peripheral Component Interconnect express (PCIe) component standard.

12. The peripheral tray system of claim 11, wherein:
the first connector component comprises a floating OCP (FLOP) connector component.

13. A system comprising:
a chassis;
a processor contained within the chassis;
a data bus coupled to the processor; and,
a peripheral mounting system comprising
a first slot, the first slot being configured to mount a first peripheral component and a first peripheral connector component, the first peripheral component and the first peripheral connector component corresponding a first component standard; and,
a second slot, the second slot being configured to mount a second peripheral component and a second peripheral connector component, the second peripheral component and the second peripheral connector component corresponding to a second component standard, the first component standard and the second component standard being different component specifications.

14. The system of claim 13, wherein:
the peripheral mounting system is configured to be mounted within an information handling system chassis conforming to a 1U information handling system form factor.

15. The system of claim 13, wherein:
the first peripheral connector component includes a first peripheral component connector;
the second peripheral connector component includes a second peripheral component connector; and,
the first peripheral component connector and the second peripheral component connector are mounted in the peripheral mounting system substantially perpendicularly to each other.

16. The system of claim 13, wherein:
the first slot includes a latching mechanism, the latching mechanism being configured to mount at least one of the first peripheral component and the first peripheral connector component to the peripheral mounting system.

17. The system of claim 13, wherein:
the first component standard comprises an open compute project (OCP) component standard; and,
the second component standard comprises a Peripheral Component Interconnect express (PCIe) component standard.

18. The system of claim 17, wherein:
the first connector component comprises a floating OCP (FLOP) connector component.
